(19) United States
(12) Patent Application Publication
(10) Pub. No.: US 2026/0107373 A1
(43) Pub. Date: Apr. 16, 2026

(54) ELECTRONIC CIRCUIT MODULE AND METHOD OF MANUFACTURING SAME

(71) Applicant: TDK CORPORATION, Tokyo (JP)

(72) Inventors: Hiromu HARADA, Tokyo (JP); Shuichi Takizawa, Tokyo (JP); Atsushi Yoshino, Tokyo (JP); Keitaro Iizasa, Tokyo (JP); Takuya Sato, Tokyo (JP)

(73) Assignee: TDK CORPORATION, Tokyo (JP)

(21) Appl. No.: 19/347,895

(22) Filed: Oct. 2, 2025

(30) Foreign Application Priority Data
Oct. 11, 2024 (JP) 2024-178732

(51) Int. Cl. H05K 1/02; H05K 1/18; H05K 3/28

(52) U.S. Cl. CPC H05K 1/023; H05K 1/181; H05K 3/28

(57) ABSTRACT

A module includes a main body, a plurality of conductor layers, an electronic component mounted on a first surface of the main body, a protective layer, and a shield layer. The protective layer includes a first covering part that covers the electronic component and the first surface and a second covering part that covers a side surface of the main body. The shield layer includes a first conductor part that covers the electronic component and the first covering part and a second conductor part that covers the main body and the second covering part. The plurality of conductor layers include a connection electrode connected to the second conductor part.

### CROSS REFERENCE TO RELATED APPLICATIONS

This application claims the benefit of Japanese Priority Patent Application No. 2024-178732 filed on Oct. 11, 2024, the entire contents of which are incorporated herein by reference.

### BACKGROUND

The present technique relates to an electronic circuit module in which an electronic component mounted on a main body such as a circuit board is covered with a protective layer and a method for manufacturing the same.

In recent years, an electronic device such as a smartphone and a personal computer has achieved multifunctionality and further miniaturization, and mounting density of an electronic circuit module (hereinafter, also simply referred to as a module) has been increased accordingly. As a result, in the electronic device, an interval between a plurality of modules mounted on a mounting board has been reduced. In order to prevent malfunction due to noise, it is preferred that a module provided with a shield on its surface be used.

JP 2004-119863 A discloses a circuit device in which a shield layer is provided on a top surface of an insulating resin covering a circuit element. In the circuit device, the shield layer is connected to an external electrode formed on a back surface side of the insulating resin via a metal film and a conductive pattern that are provided in a through-hole formed in the insulating resin. The conductive pattern electrically connected to the shield layer is a conductive pattern having a ground potential.

JP 2015-115549 A discloses a semiconductor device in which a semiconductor chip is mounted on a substrate, the semiconductor chip is covered with a sealing resin layer, and the front surface of the sealing resin layer and the side surface of the substrate are covered with a shield layer. In the semiconductor device, the shield layer is connected to an external connection terminal via a wiring layer provided to the substrate, and is grounded via the wiring layer and the external connection terminal.

U.S. Pat. No. 11,222,793 discloses an electronic circuit module in which a semiconductor die is mounted on a substrate, and the semiconductor die is covered with a first sealing material. In the electronic circuit module, the substrate and the first sealing material are covered with a non-conductive second sealing material. On the substrate, a conductive layer extending in a perpendicular direction and a horizontal direction is formed.

In order to improve reliability of a module and an electronic device, it is preferred that not only an electronic component but also a circuit board be protected as in the electronic circuit module disclosed in U.S. Pat. No. 11,222,793. Herein, as in the electronic circuit module disclosed in U.S. Pat. No. 11,222,793, consideration is given to providing a shield layer to an electronic circuit module entirely covered with a sealing material. In order to exert the function of the shield layer effectively, it is preferred that the shield layer be connected to the ground as in the techniques disclosed in JP 2004-119863 A and JP 2015-115549 A. However, when the entire region is covered with the sealing material, the shield layer cannot be connected to the ground.

As in the technique disclosed in JP 2004-119863 A, when a conductive layer that connects a shield layer to the ground and passes through a sealing material and a circuit board is provided, there arise a problem that a step of forming the conductive layer is additionally required, which increases the cost, and a problem that the circuit board design is limited.

### SUMMARY

An electronic circuit module according to an embodiment of the present technique includes a main body including a first surface and a second surface that face opposite to each other, and four side surfaces that connect the first surface and the second surface to each other, a plurality of conductor layers provided inside the main body, an electronic component mounted on the first surface of the main body, a protective layer formed of an insulating material, and a shield layer formed of a conductive material. The protective layer includes a first covering part that covers the electronic component and the first surface and a second covering part that covers at least one side surface of the four side surfaces. The shield layer includes a first conductor part that covers the electronic component and the first covering part and a second conductor part that covers the main body and the second covering part. The plurality of conductor layers include at least one connection electrode connected to the second conductor part.

A method of manufacturing an electronic circuit module according to an embodiment of the present technique includes forming the main body and the plurality of conductor layers, mounting the electronic component on the main body, forming an initial protective layer so as to cover the main body and the electronic component, removing a part of the initial protective layer and forming the protective layer so as to form the first covering part and the second covering part, and forming the shield layer.

Objects, features, and advantages of the present technique will appear more fully from the following description.

### BRIEF DESCRIPTION OF THE DRAWINGS

The accompanying drawings are included to facilitate understanding of the present disclosure, are incorporated in this specification, and constitute a part thereof. The drawings illustrate example embodiments and, serve to describe the principle of the present technique together with this specification.

FIG. 1 is a cross-sectional view showing an electronic circuit module according to a first example embodiment of the present technique.

FIG. 2 is a cross-sectional view showing the electronic circuit module according to the first example embodiment of the present technique.

FIG. 3 is a plan view showing the electronic circuit module according to the first example embodiment of the present technique.

FIG. 4 is a perspective view showing a main body and a protective layer in the first example embodiment of the present technique.

FIG. 5 is a perspective view showing the main body and the protective layer in the first example embodiment of the present technique.

FIG. 6 is a perspective view showing the electronic circuit module according to the first example embodiment of the present technique.

FIG. 7 is a perspective view showing the electronic circuit module according to the first example embodiment of the present technique.

FIG. 8 is a cross-sectional view showing a corner portion of a first covering part and the vicinity thereof in the first example embodiment of the present technique.

FIG. 9 is a cross-sectional view showing an end portion of a second covering part and the vicinity thereof in the first example embodiment of the present technique.

FIG. 10 is a cross-sectional view showing an end portion of a second conductor part and the vicinity thereof in the first example embodiment of the present technique.

FIG. 11 is a flowchart showing a method of manufacturing an electronic circuit module according to the first example embodiment of the present technique.

FIG. 12 is a perspective view showing a step in the method of manufacturing an electronic circuit module according to the first example embodiment of the present technique.

FIG. 13 is a cross-sectional view showing the step shown in FIG. 12.

FIG. 14 is a cross-sectional view showing a step subsequent to the step shown in FIG. 12 and FIG. 13.

FIG. 15 is a cross-sectional view showing a step subsequent to the step shown in FIG. 14.

FIG. 16 is a plan view showing a step subsequent to the step shown in FIG. 15.

FIG. 17 is a cross-sectional view showing the step shown in FIG. 16.

FIG. 18 is a cross-sectional view showing the step shown in FIG. 16.

FIG. 19 is a plan view showing a step subsequent to the step shown in FIG. 16 to FIG. 18.

FIG. 20 is a cross-sectional view showing the step shown in FIG. 19.

FIG. 21 is a cross-sectional view showing a step subsequent to the step shown in FIG. 19 and FIG. 20.

FIG. 22 is a cross-sectional view showing a first modification example of the end portion of the second covering part in the first example embodiment of the present technique.

FIG. 23 is a cross-sectional view showing a second modification example of the end portion of the second covering part in the first example embodiment of the present technique.

FIG. 24 is a cross-sectional view showing a third modification example of the end portion of the second covering part in the first example embodiment of the present technique.

FIG. 25 is a cross-sectional view showing a fourth modification example of the end portion of the second covering part in the first example embodiment of the present technique.

FIG. 26 is a cross-sectional view showing a fifth modification example of the end portion of the second covering part in the first example embodiment of the present technique.

FIG. 27 is a cross-sectional view showing a sixth modification example of the end portion of the second covering part in the first example embodiment of the present technique.

FIG. 28 is a cross-sectional view showing an electronic circuit module according to a second example embodiment of the present technique.

FIG. 29 is a plan view showing the electronic circuit module according to the second example embodiment of the present technique.

FIG. 30 is a cross-sectional view showing an electronic circuit module according to a third example embodiment of the present technique.

FIG. 31 is a plan view showing the electronic circuit module according to the third example embodiment of the present technique.

FIG. 32 is a plan view showing an electronic circuit module according to a fourth example embodiment of the present technique.

FIG. 33 is a cross-sectional view showing an electronic circuit module according to a fifth example embodiment of the present technique.

FIG. 34 is a cross-sectional view showing the electronic circuit module according to the fifth example embodiment of the present technique.

FIG. 35 is a plan view showing the electronic circuit module according to the fifth example embodiment of the present technique.

### DETAILED DESCRIPTION

An object of the present technique is to provide an electronic circuit module and a method of manufacturing the same that can effectively exert a function of a shield layer while improving reliability.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

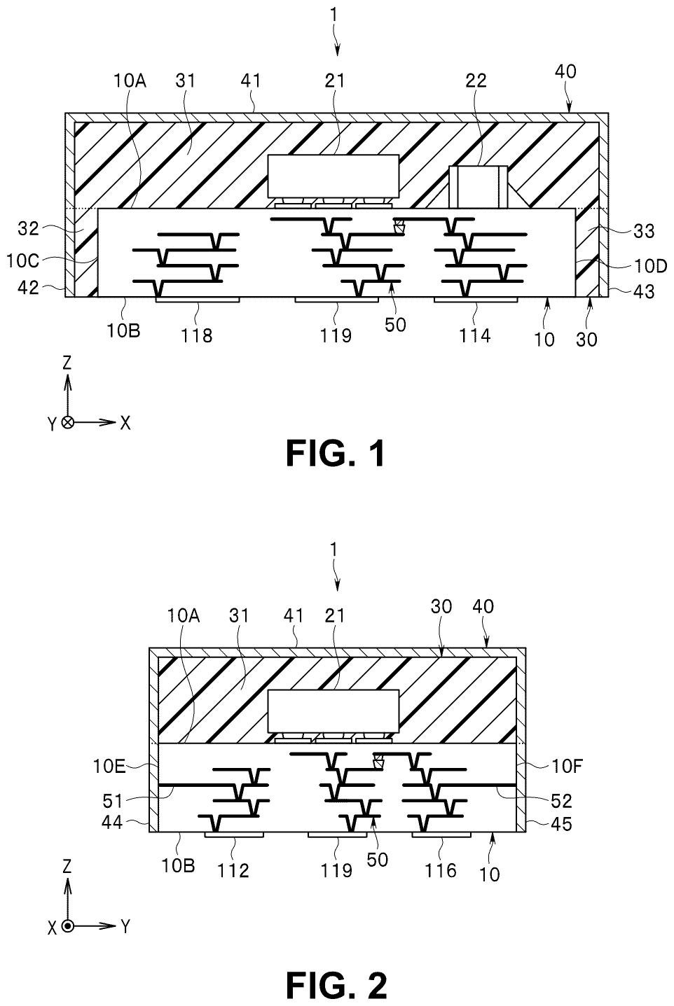

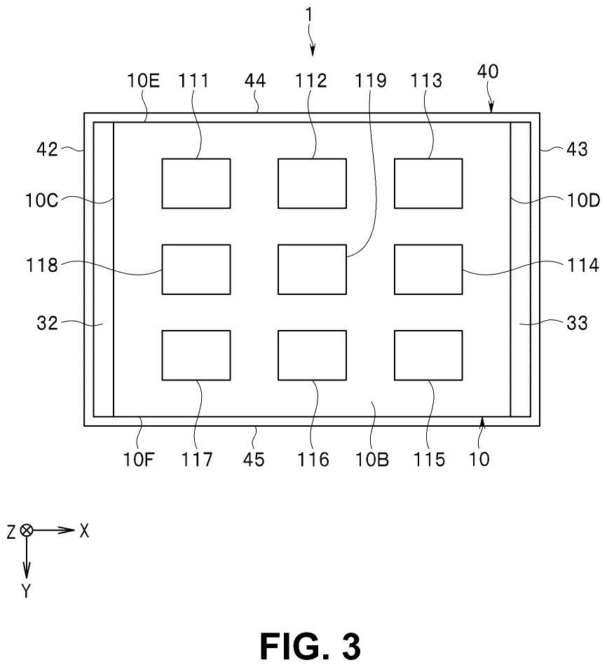

First, with reference to FIG. 1 to FIG. 3, description is made on an overview of a structure of an electronic circuit module (hereinafter, simply referred to as a module) 1 according to a first example embodiment of the present technique. FIG. 1 and FIG. 2 are cross-sectional views showing the module 1. FIG. 3 is a plan view showing the module 1.

The module 1 is used in an electronic device such as a smartphone and a personal computer. For example, the module 1 may be an electronic circuit module including a filter function such as a bandpass filter, or may be an electronic circuit module including a demultiplexer function such as a diplexer or a triplexer.

The module 1 includes a main body 10 and electronic components 21 and 22 that are mounted on the main body 10. For example, at least one of the electronic components 21 and 22 may be an active element such as a transistor and a semiconductor IC, may be a passive element such as an inductor and a capacitor, or may be a resonator or a filter. Each of the electronic components 21 and 22 includes an element or a circuit as described above, and a plurality of terminals that are connected to the element or the circuit. Note that the number of electronic components mounted on the main body 10 is not limited to two, and may be one, three, or more.

The main body 10 may be used as a circuit board of the electronic components 21 and 22, and may include an electronic circuit connected to the electronic components 21 and 22. The electronic circuit may include a function as a wiring line. The electronic circuit may further include a function of a filter, a balun, a directional coupler, a branching filter, or the like, for example.

Herein, as shown in FIG. 1 to FIG. 3, an X direction, a Y direction, and a Z direction are defined. The X direction, the Y direction, and the Z direction are orthogonal to one another. The opposite directions to the X, Y, and Z directions are referred to as −X, −Y, and −Z directions, respectively. The expression “as viewed in a specific direction (for example, the Z direction)” indicates that a target object is viewed in a specific direction or from a position separated in a direction parallel to the specific direction, in other words, a target object is viewed in plan view.

The main body 10 has a rectangular parallelepiped shape. The main body 10 includes a first surface 10A and a second surface 10B that face opposite to each other and four side surfaces 10C to 10F that connect the first surface 10A and the second surface 10B to each other. The side surfaces 10C and 10D face opposite to each other, and the side surfaces 10E and 10F also face opposite to each other. The side surfaces 10C to 10F may be perpendicular to the first surface 10A and the second surface 10B.

As shown in FIG. 1 and FIG. 2, the first surface 10A is positioned at the end of the main body 10 in the Z direction. The first surface 10A also serves as the top surface of the main body 10. The second surface 10B is positioned at the end of the main body 10 in the −Z direction. The second surface 10B also serves as the bottom surface of the main body 10. FIG. 3 shows the module 1 as viewed from the second surface 10B side.

The side surface 10C is positioned at the end of the main body 10 in the −X direction. The side surface 10D is positioned at the end of the main body 10 in the X direction. The side surface 10E is positioned at the end of the main body 10 in the −Y direction. The side surface 10F is positioned at the end of the main body 10 in the Y direction. FIG. 1 shows a cross-section of the module 1 that is parallel to the side surfaces 10E and 10F. FIG. 2 shows a cross-section of the module 1 that is parallel to the side surfaces 10C and 10D.

The electronic components 21 and 22 are mounted on the first surface 10A of the main body 10. The main body 10 includes a plurality of electrodes provided on the first surface 10A. A plurality of terminals of the electronic component 21 and a plurality of terminals of the electronic component 22 that are electrically connected to the electronic circuit of the main body 10 are connected directly to the plurality of electrodes or indirectly thereto via a plurality of bumps. The main body 10 may include a plurality of insulating layers being stacked. The first surface 10A and the second surface 10B are positioned at both ends in the stacking direction of the plurality of insulating layers.

The main body 10 or the plurality of insulating layers may be formed of a brittle material. Specifically, each of the plurality of insulating layers may be formed of a ceramic material such as low-temperature co-fired ceramics (LTCC). Alternatively, the main body 10 or the plurality of insulating layers may be formed of an organic insulating material, or may be formed of a composite material containing a ceramic material and an organic insulating material.

The module 1 further includes a protective layer 30. The protective layer 30 covers the electronic components 21 and 22, the first surface 10A of the main body 10, and at least a part of the four side surfaces 10C to 10F. As the material of the protective layer 30, an insulating material containing a resin material may be used. The resin material may be a thermosetting resin or a thermoplastic resin. As the resin material, epoxy resin, silicone resin, polyimide resin, polyamide-imide resin, phenol resin, acrylic resin, or urethane resin is used, for example. The material of the protective layer 30 may contain a material other than the resin material, and may contain, for example, a filler in addition to the resin material. As the filler, silicon oxide, aluminum oxide, magnesium oxide, silicon nitride, or a composite material thereof is used, for example. When the material of the protective layer 30 contains the resin material and the filler, the filler preferably has a weight filling ratio greater than 75 wt % and less than 93 wt %.

Note that the protective layer 30 may contact with the plurality of terminals of each of the electronic components 21 and 22 and the plurality of bumps. Alternatively, the protective layer 30 may include a plurality of insulating portions formed of different insulating materials. In such a case, a first insulating portion being one of the plurality of insulating portions may be arranged mainly in the periphery of the plurality of terminals of each of the electronic components 21 and 22 and the plurality of bumps, and a second insulating portion being the other one of the plurality of insulating portions may mainly cover the first surface 10A and the front surfaces of the electronic components 21 and 22. The second insulating portion may or may not contact with the plurality of terminals of each of the electronic components 21 and 22 and the plurality of bumps.

The module 1 further includes a shield layer 40 formed of a conductive material. The shield layer 40 covers the main body 10, the electronic components 21 and 22, and the protective layer 30. The conductive material may be pure metal composed of a single metal element, or an alloy composed of a plurality of metal elements. As the conductive material, for example, Cu, Ag, Au, Al, Ti, Cr, or stainless steel is used.

Next, with reference to FIG. 1 to FIG. 3, the main body 10 is further described in detail. The module 1 further includes a plurality of conductor layers 50 inside the main body 10. The plurality of conductor layers 50 form the electronic circuit of the main body 10. When the main body 10 includes the plurality of insulating layers, each of the plurality of conductor layers 50 is formed along the surface of the insulating layer. In such a case, among the plurality of conductor layers 50, two conductor layers 50 adjacent to each other at an interval in a direction parallel to the Z direction can be connected to each other via a through-hole passing through the insulating layer. For example, one of the two conductor layers 50 may be connected to the other of the two conductor layers 50 via a through-hole, or the two conductor layers 50 may be connected to each other via a conductor filling a through-hole.

The main body 10 includes a plurality of terminals provided on the second surface 10B of the main body 10. In the example shown in FIG. 1 to FIG. 3, the main body 10 includes nine terminals 111, 112, 113, 114, 115, 116, 117, 118, and 119. The terminals 111, 112, and 113 are arrayed in the stated order in the X direction at the positions closer to the side surface 10E with respect to the side surface 10F. The terminals 115, 116, and 117 are arrayed in the stated order in the −X direction at the positions closer to the side surface 10F with respect to the side surface 10E.

The terminal 114 is arranged between the terminal 113 and the terminal 115. The terminal 118 is arranged between the terminal 111 and the terminal 117. The terminal 119 is arranged between the terminal 112 and the terminal 116. The terminal 119 is arranged substantially at the center of the second surface 10B.

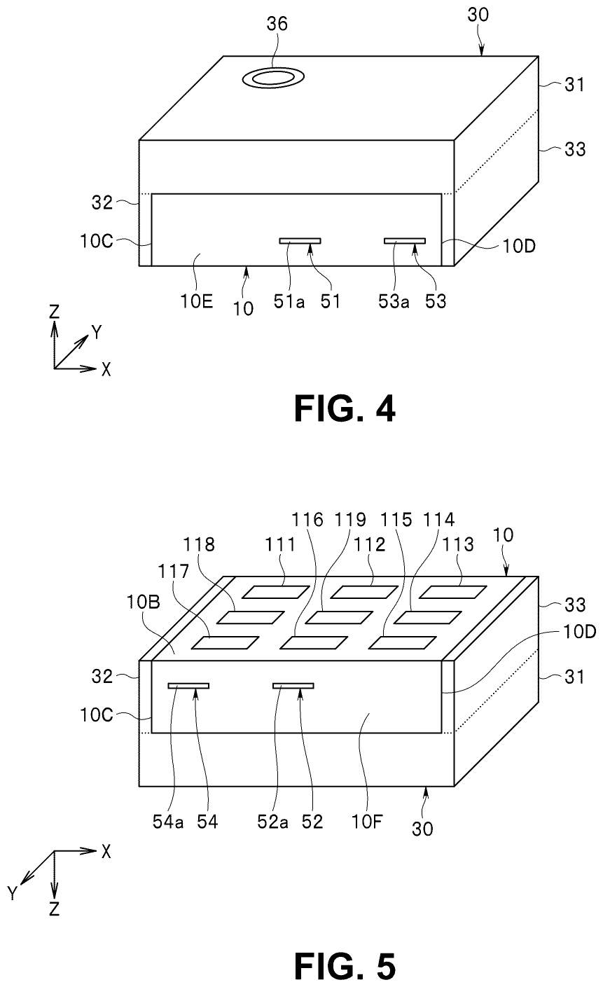

Next, with reference to FIG. 1 to FIG. 5, the protective layer 30 is further described in detail. FIG. 4 and FIG. 5 are perspective views showing the main body 10 and the protective layer 30. The protective layer 30 includes a first covering part 31 that covers the electronic components 21 and 22 and the first surface 10A of the main body 10 and a second covering part that covers at least one side surface of the four side surfaces of the main body 10. The first covering part 31 is arranged in front of the first surface 10A of the main body 10 in the Z direction.

The first covering part 31 includes a top surface positioned at the end of the first covering part 31 in the Z direction, a first side surface positioned at the end of the first covering part 31 in the −X direction, a second side surface positioned at the end of the first covering part 31 in the X direction, a third side surface positioned at the end of the first covering part 31 in the −Y direction, and a fourth side surface positioned at the end of the first covering part 31 in the Y direction.

The first covering part 31 further includes a plurality of corner portions that are present at positions at which the top surface and two or three surfaces of the first side surface to the fourth side surface of the first covering part 31 intersect with each other. Each of the plurality of corner portions may or may not be chamfered. When each of the plurality of corner portions is chamfered, each of the plurality of corner portions may be rounded.

The first covering part 31 includes a mark 36. At least a part of the mark 36 may be recessed from the periphery, or may protrude from the periphery. A planar shape of the mark 36 (a shape as viewed in the Z direction) may be a freely-selected figure or a freely-selected symbol, or may be at least one character.

The second covering part may cover all or substantially all of at least one side surface, or may cover a part of at least one side surface. In the example embodiment, in particular, the second covering part covers the side surfaces 10C and 10D without covering the side surfaces 10E and 10F. Hereinafter, a part of the second covering part that covers the side surface 10C is referred to as a second covering part 32, and a part thereof that covers the side surface 10D is referred to as a second covering part 33. The second covering part 32 covers all or substantially all of the side surface 10C. The second covering part 33 covers all or substantially all of the side surface 10D. The second covering parts 32 and 33 are continuous to the first covering part 31. In FIG. 1, FIG. 4, and FIG. 5, the boundary between the first covering part 31 and the second covering parts 32 and 33 is shown by the dotted line.

A dimension of the main body 10 in a direction parallel to the X direction and a dimension of the main body 10 in a direction parallel to the Y direction each fall within a range from 500 μm to 5,000 μm, for example. In such a case, in view of protection of the main body 10, for example, a dimension of each of the second covering parts 32 and 33 in a direction parallel to the X direction preferably falls within a range from 5 μm to 300 μm, more preferably, a range from 15 μm to 95 μm.

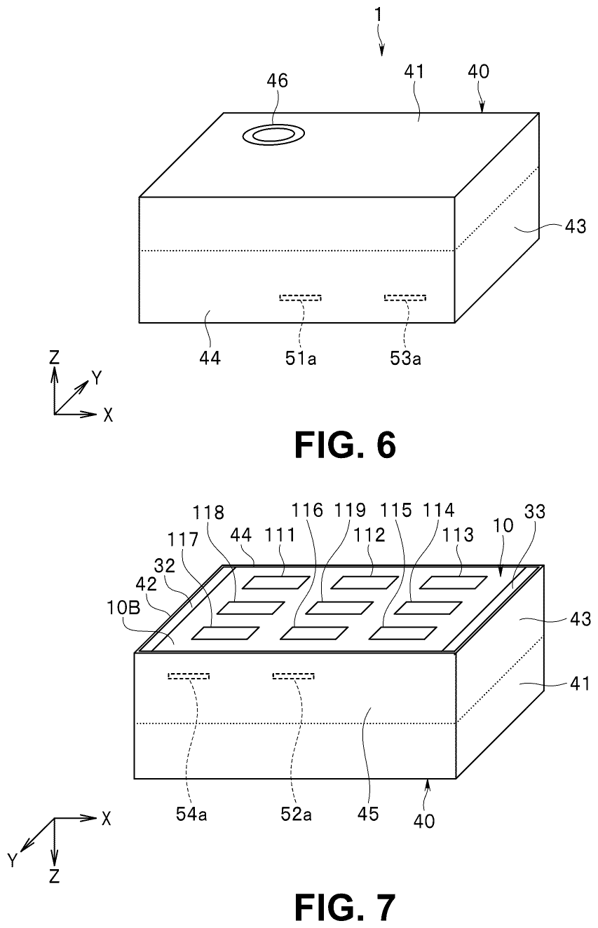

Next, with reference to FIG. 1 to FIG. 3, FIG. 6, and FIG. 7, the shield layer 40 is described in detail. FIG. 6 and FIG. 7 are perspective views showing the module 1. The shield layer 40 includes a first conductor part 41 that covers the electronic component 21 and the first covering part 31. The first covering part 31 is interposed between the electronic component 21 and the first conductor part 41.

The first conductor part 41 includes a mark 46. The mark 46 may have a shape corresponding to the mark 36. In other words, at least a part of the mark 46 may be recessed from the periphery, or may protrude from the periphery. A planar shape of the mark 46 (a shape as viewed in the Z direction) may be a freely-selected figure, or may be at least one character. For example, the mark 46 is used to recognize the positions of the terminals 111 to 119 of the module 1.

The shield layer 40 further includes a second conductor part that covers the main body 10 and the second covering parts 32 and 33. In the example embodiment, in particular, the second conductor part covers the side surfaces 10E and 10F of the main body 10 and the second covering parts 32 and 33. Hereinafter, a part of the second conductor part that covers the second covering part 32 is referred to as a second conductor part 42, a part thereof that covers the second covering part 33 is referred to as a second conductor part 43, a part thereof that covers the side surface 10E is referred to as a second conductor part 44, and a part thereof that covers the side surface 10F is referred to as a second conductor part 45. The second conductor parts 42 to 45 are continuous to the first conductor part 41. In FIG. 1, FIG. 2, FIG. 6, and FIG. 7, the boundary between the first conductor part 41 and the second conductor parts 42 to 45 is shown by the dotted line.

The second conductor part 42 covers all or substantially all of the second covering part 32. The second conductor part 42 covers the side surface 10C of the main body 10 via the second covering part 32.

The second conductor part 43 covers all or substantially all of the second covering part 33. The second conductor part 43 covers the side surface 10D of the main body 10 via the second covering part 33.

The second conductor part 44 directly covers all or substantially all of the side surface 10E of the main body 10. The second conductor part 45 directly covers all or substantially all of the side surface 10F of the main body 10.

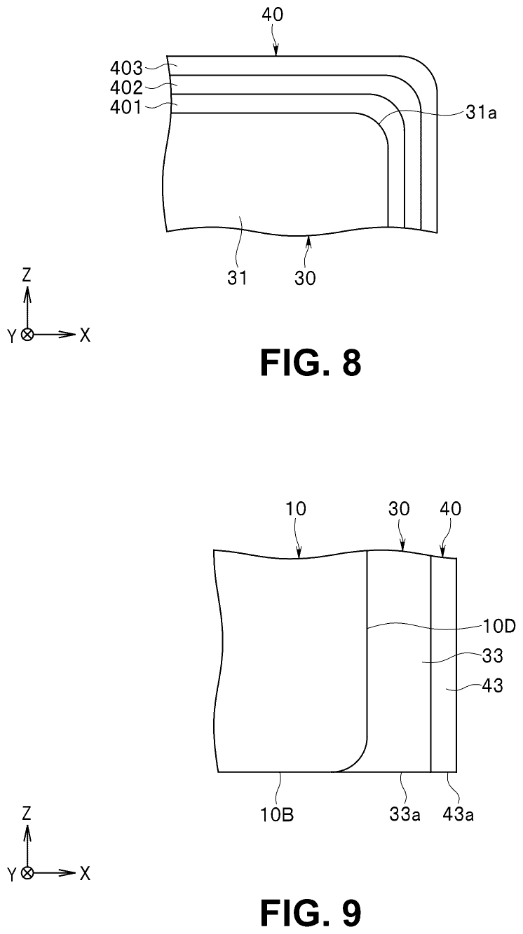

The shield layer 40 preferably includes a plurality of metal layers. Herein, with reference to FIG. 8, description is made on a case in which the shield layer 40 includes a plurality of metal layers being stacked. FIG. 8 is a cross-sectional view showing a corner portion of the first covering part 31 and the vicinity thereof.

In the example shown in FIG. 8, the shield layer 40 includes three metal layers 401, 402, and 403 being stacked as the plurality of metal layers. Each of the metal layers 401, 402, and 403 includes a first part forming the first covering part 31 and a second part forming the second covering part. The second part is continuous to the first part.

The metal layer 401 covers the front surface of the protective layer 30 and the side surfaces 10E and 10F of the main body 10. The metal layer 402 covers all or substantially all of the metal layer 401. The metal layer 403 covers all or substantially all of the metal layer 402.

The metal layer 402 may be formed of Cu, Ag, Au, or Al. Each of the metal layers 401 and 403 may be formed of Cr, Ti, or stainless steel. The thickness of each of the metal layers 401 and 403 may be or may not be the same as the thickness of the metal layer 402. In the latter case, the thickness of each of the metal layers 401 and 403 is preferably smaller than that of the metal layer 402. In particular, the thickness of the metal layer 401 preferably falls within a range from 50 nm to 200 nm, for example.

Note that the configuration of the shield layer 40 is not limited to the example shown in FIG. 8, and may be formed of one metal layer.

Note that FIG. 8 shows a corner portion 31a of the first covering part 31 that is present at the position at which the top surface and the second side surface of the first covering part 31 intersect with each other. In the example shown in FIG. 8, the corner portion 31a is rounded. Thus, the part of the shield layer 40 that covers the corner portion 31a is also rounded. Although omitted in illustration, when the corner portion of the first covering part 31 other than the corner portion 31a is rounded, a part of the shield layer 40 that covers the corner portion of the first covering part 31 other than the corner portion 31a is also rounded.

Next, with reference to FIG. 2 and FIG. 4 to FIG. 7, the relationship between the shield layer 40 and the plurality of conductor layers 50 is described. The plurality of conductor layers 50 include at least one connection electrode connected to at least one of the second conductor parts 44 and 45 of the shield layer 40. In the example embodiment, in particular, the plurality of conductor layers 50 preferably include at least one connection electrode connected to the second conductor part 44 covering the side surface 10E and at least the other one connection electrode connected to the second conductor part 45 covering the side surface 10F. In the example shown in FIG. 2 and FIG. 4 to FIG. 7, the plurality of conductor layers 50 include two connection electrodes 51 and 53 that are connected to the second conductor part 44 and two connection electrodes 52 and 54 that are connected to the second conductor part 45.

The connection electrode 51 includes an end surface 51a exposed at the side surface 10E. The connection electrode 53 includes an end surface 53a exposed at the side surface 10E. The end surfaces 51a and 53a are positioned between the first surface 10A and the second surface 10B of the main body 10 in a direction parallel to the Z direction. The end surfaces 51a and 53a may be at the same position in a direction parallel to the Z direction, or may be at different positions in a direction parallel to the Z direction. The second conductor part 44 is connected to the end surfaces 51a and 53a.

An interval between the end surface 51a (the end surface 53a) and the second surface 10B in a direction parallel to the Z direction (hereinafter, referred to as a first interval) may be the same or substantially the same as an interval between the end surface 51a (the end surface 53a) and the first surface 10A in a direction parallel to the Z direction (hereinafter, referred to as a second interval), or may be different therefrom. In the latter case, the first interval may be smaller than the second interval.

The connection electrode 52 includes an end surface 52a exposed at the side surface 10F. The end surfaces 52a and 54a are positioned between the first surface 10A and the second surface 10B of the main body 10 in a direction parallel to the Z direction. The connection electrode 54 includes an end surface 54a exposed at the side surface 10F. The end surfaces 52a and 54a may be at the same position in a direction parallel to the Z direction, or may be at different positions in a direction parallel to the Z direction. The second conductor part 45 is connected to the end surfaces 52a and 54a.

An interval between the end surface 52a (the end surface 54a) and the second surface 10B in a direction parallel to the Z direction (hereinafter, referred to as a third interval) may be the same or substantially the same as an interval between the end surface 52a (the end surface 54a) and the first surface 10A in a direction parallel to the Z direction (hereinafter, referred to as a fourth interval), or may be different therefrom. In the latter case, the third interval may be smaller than the fourth interval.

Each of the connection electrodes 51 to 54 is an electrode connected to the ground. FIG. 2 shows an example in which the connection electrode 51 is connected to the terminal 112 via some of the conductor layers 50 and the connection electrode 52 is connected to the terminals 116 and 119 via the other conductor layers 50. In this example, the terminals 112, 116, and 119 are connected to the ground. Although omitted in illustration, each of the connection electrodes 53 and 54 is also connected to at least one terminal of the terminals 111 to 119 via the plurality of conductor layers 50. At least one terminal to which each of the connection electrodes 51 to 54 is connected is a ground terminal connected to the ground. The at least one terminal is connected to the ground, and thus the shield layer 40 is electrically connected to the ground.

A dimension of the module 1 in a direction parallel to the Z direction falls within a range from 300 μm to 1,000 μm, for example. In such a case, in view of exerting the function of the shield layer 40 effectively, an interval between the second surface 10B of the main body 10 and each of the connection electrodes 51 to 54 in a direction parallel to the Z direction preferably falls within a range 40 μm to 180 μm.

Note that the number of the connection electrodes is not limited to the example shown in FIG. 2 and FIG. 4 to FIG. 7. The number of the connection electrodes may be one, or may be five or more. However, in view of exerting the function of the shield layer 40 effectively, the number of the connection electrodes is preferably two or more. In view of exerting the function of the shield layer 40 effectively, the total area of the end surfaces of the connection electrodes is preferably 300 μm² or more, for example.

Next, the ends of the second covering parts 32 and 33 of the protective layer 30 are described. Herein, with reference to FIG. 9, the second covering part 33 is described as an example. FIG. 9 is a cross-sectional view showing the end portion of the second covering part 33 and the vicinity thereof. The second covering part 33 includes an end portion 33a that is farthest from the first covering part 31 and is positioned at the end of the second covering part 33 in the −Z direction. In the example shown in FIG. 9, the position of the end portion 33a of the second covering part 33 in a direction parallel to the Z direction is the same or substantially the same as the position of the second surface 10B of the main body 10 in a direction parallel to the Z direction.

The above-given description of the second covering part 33 is also applicable to the second covering part 32. In other words, the second covering part 32 includes an end portion that is farthest from the first covering part 31 and is positioned at the end of the second covering part 32 in the −Z direction. The position of the end portion of the second covering part 32 in a direction parallel to the Z direction is the same or substantially the same as the position of the end portion of the second surface 10B of the main body 10 in a direction parallel to the Z direction.

As shown in FIG. 9, the corner portion that is present at the position at which the second surface 10B and the side surface 10D of the main body 10 intersect with each other may be rounded. The second covering part 33 may cover the corner portion. Similarly, the corner portion that is present at the position at which the second surface 10B and the side surface 10C of the main body 10 intersect with each other may be rounded. The second covering part 32 may cover the corner portion.

Note that FIG. 9 shows an end portion 43a that is an end portion of the second conductor part 43 of the shield layer 40 and is farthest from the first conductor part 41. The end portion 43a of the second conductor part 43 is positioned at the end of the second conductor part 43 in the −Z direction. In the example shown in FIG. 9, the position of the end portion 43a of the second conductor part 43 in a direction parallel to the Z direction is the same or substantially the same as the position of the second surface 10B of the main body 10 in a direction parallel to the Z direction.

The above-given description of the second conductor part 43 is also applicable to the second conductor part 42 of the shield layer 40. In other words, the second conductor part 42 includes an end portion that is farthest from the first conductor part 41 and is positioned at the end of the second conductor part 42 in the −Z direction. The position of the end portion of the second conductor part 42 in a direction parallel to the Z direction is the same or substantially the same as the position of the second surface 10B of the main body 10 in a direction parallel to the Z direction.

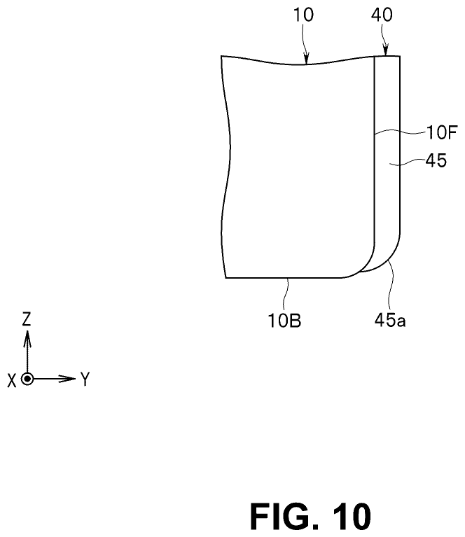

Next, with reference to FIG. 10, the end portions of the second conductor parts 44 and 45 of the shield layer 40 are described. Herein, with reference to FIG. 10, description is made on the second conductor part 45 as an example. FIG. 10 is a cross-sectional view showing the end portion of the second conductor part 45 and the vicinity thereof. The second conductor part 45 includes an end portion 45a that is farthest from the first conductor part 41 and is positioned at the end of the second conductor part 45 in the −Z direction.

At least a part of the end portion 45a of the second conductor part 45 is inclined with respect to a direction perpendicular to the side surface 10F of the main body 10. A dimension of the second conductor part 45 in a direction perpendicular to the side surface 10F of the main body 10 (a direction parallel to the Y direction) may be reduced as approaching the second surface 10B of the main body 10. A dimension of the second conductor part 45 in a direction perpendicular to the second surface 10B of the main body 10 (a direction parallel to the Z direction) is reduced as being separated away from the side surface 10F of the main body 10.

The end portion 45a of the second conductor part 45 may have a shape protruding in a direction away from each of the first surface 10A (see FIG. 1 and FIG. 2) and the side surface 10F of the main body 10. The end portion 45a of the second conductor part 45 may be rounded.

The above-given description of the second conductor part 45 is also applicable to the second conductor part 44. In other words, the second conductor part 44 includes an end portion that is farthest from the first conductor part 41 and is positioned at the end of the second conductor part 44 in the −Z direction. At least a part of the end portion of the second conductor part 44 is inclined with respect to a direction perpendicular to the side surface 10E (see FIG. 2 to FIG. 4) of the main body 10.

As shown in FIG. 10, the corner portion that is present at the position at which the second surface 10B and the side surface 10F of the main body 10 intersect with each other may be rounded. The second conductor part 45 may cover the corner portion. Similarly, the corner portion that is present at the position at which the second surface 10B and the side surface 10E of the main body 10 intersect with each other may be rounded. The second conductor part 44 may cover the corner portion.

Next, the method of manufacturing the module 1 is described. The method of manufacturing the module 1 includes a step of forming the main body 10 and the plurality of conductor layers 50, a step of mounting the electronic components 21 and 22 on the main body 10, a step of forming an initial protective layer so as to cover the main body 10 and the electronic components 21 and 22, a step of removing a part of the initial protective layer and forming the protective layer 30 so as to form the first covering part 31 and the second covering part 32, and a step of forming the shield layer 40.

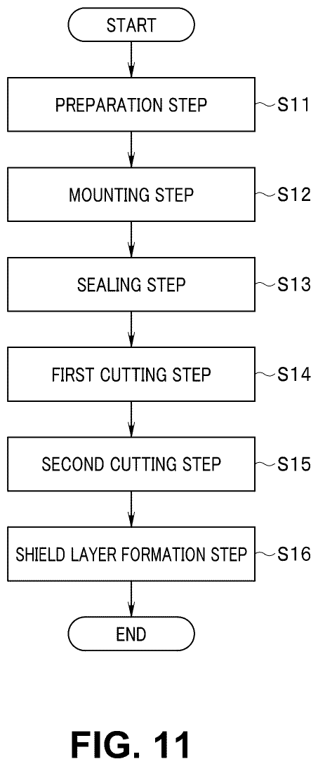

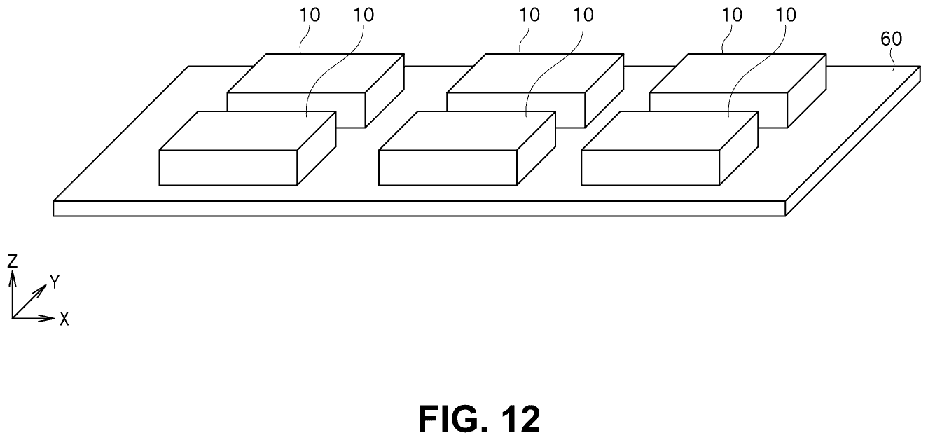

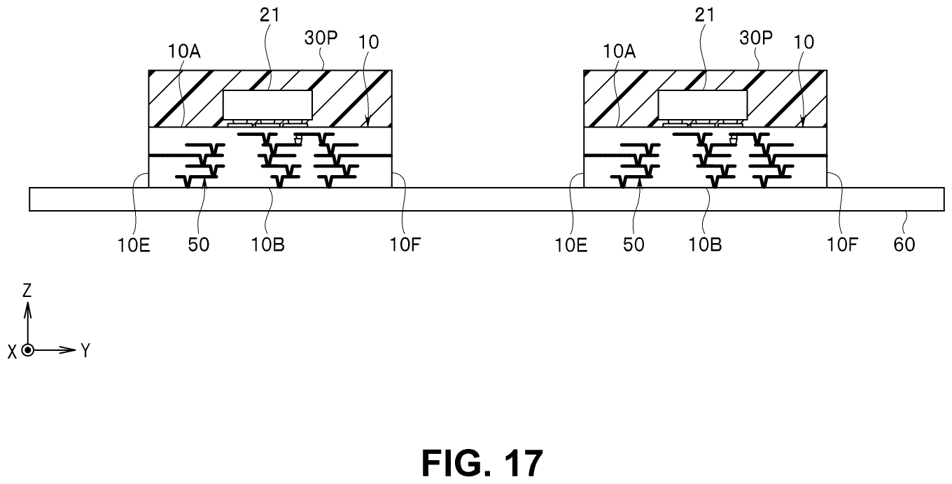

Hereinafter, with reference to FIG. 11 to FIG. 21, description is made on the procedure from the step of forming the main body 10 and the plurality of conductor layers 50 to the step of forming the shield layer 40. Herein, a method of manufacturing the plurality of modules 1 is described. FIG. 11 is a flowchart showing the method of manufacturing the module 1. The method of manufacturing the module 1 includes a preparation step S11, a mounting step S12, a sealing step S13, a first cutting step S14, a second cutting step S15, and a shield layer formation step S16.

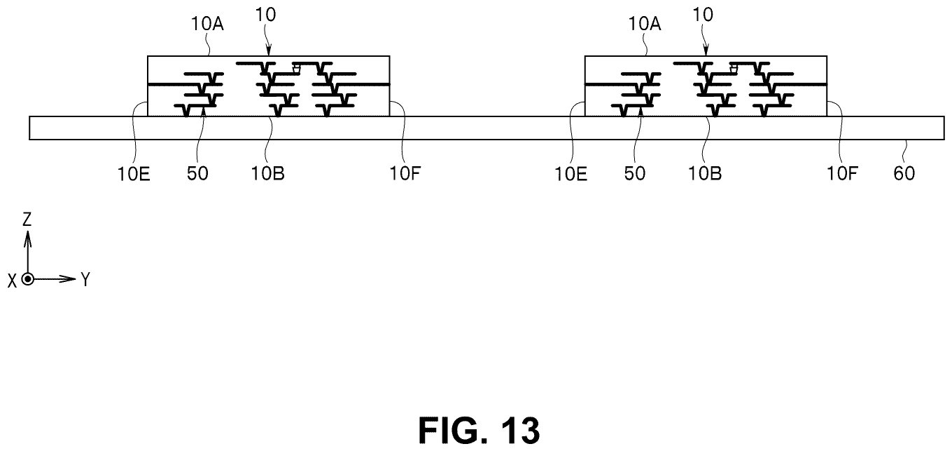

FIG. 12 and FIG. 13 show the preparation step S11. In this step, a plurality of main bodies 10 are fixed onto a substrate 60 by using a tape omitted in illustration, for example. Note that, in FIG. 13, terminals 111 to 119 of the main body 10 (see FIG. 1 to FIG. 3) are omitted.

The plurality of main bodies 10 are arrayed in a lattice pattern along a plurality of dicing lines extending in a lattice pattern. Hereinafter, a plurality of dicing lines extending in respective directions parallel to the X direction are referred to as a plurality of first dicing lines, and a plurality of dicing lines extending in respective directions parallel to the Y direction are referred to as a plurality of second dicing lines. One main body 10 is arranged between two first dicing lines that are adjacent to each other at an interval in a direction parallel to the Y direction and between two second dicing lines that are adjacent to each other at an interval in a direction parallel to the X direction.

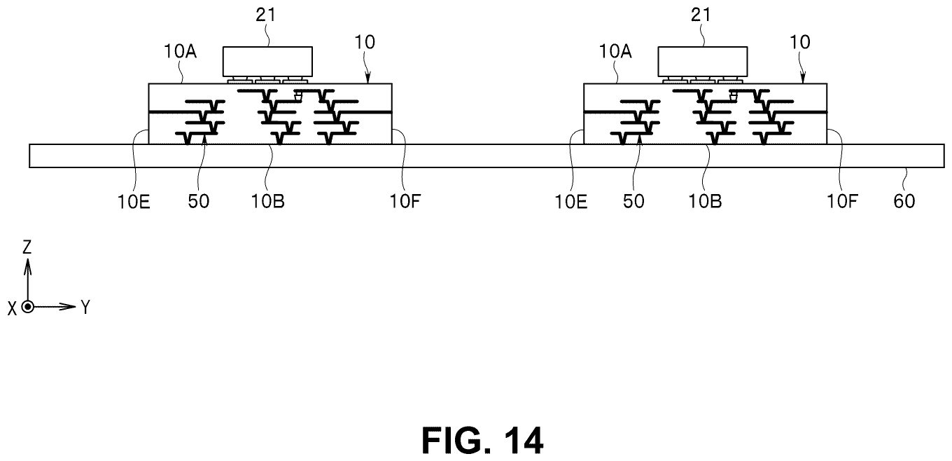

FIG. 14 shows the subsequent step, in other words, the mounting step S12. In this step, the electronic component 21 and the electronic component 22 (see FIG. 1) are mounted on the first surface 10A of each of the plurality of main bodies 10.

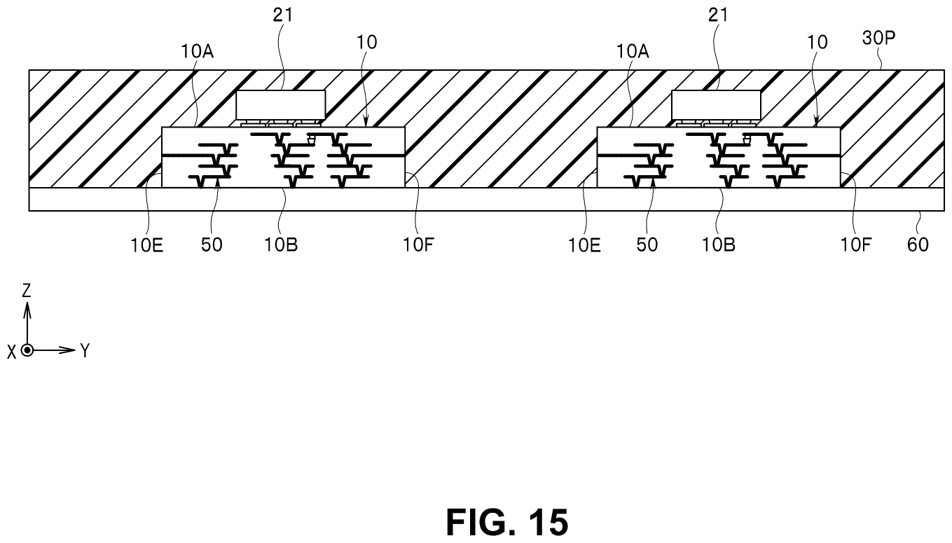

FIG. 15 shows the subsequent step, in other words, the sealing step S13. In this step, an initial protective layer 30P that later serve as the plurality of protective layers 30 is formed so as to cover a plurality of structures each including the main body 10 and the electronic components 21 and 22.

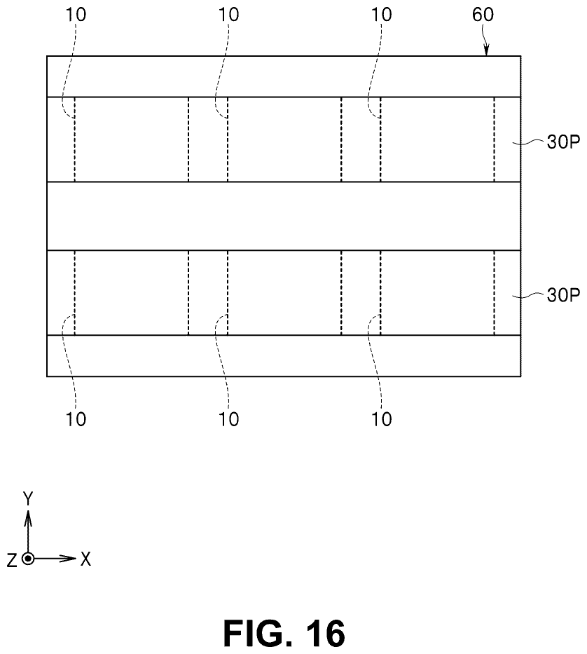

FIG. 16 to FIG. 18 show the subsequent step, in other words, the first cutting step S14. In this step, a part of the initial protective layer 30P is removed by cutting the initial protective layer 30P along each of the plurality of first dicing lines.

In the first cutting step S14, the initial protective layer 30P may be cut so as to expose the side surfaces 10E and 10F of each of the plurality of main bodies 10. Alternatively, a part of each of the plurality of main bodies 10 may be cut together with the initial protective layer 30P. In such a case, two cross-sections of the main body 10 serve as the side surfaces 10E and 10F, respectively. The end surface 51a of the connection electrode 51, the end surface 52a of the connection electrode 52, the end surface 53a of the connection electrode 53, and the end surface 54a of the connection electrode 54 are exposed by executing the first cutting step S14.

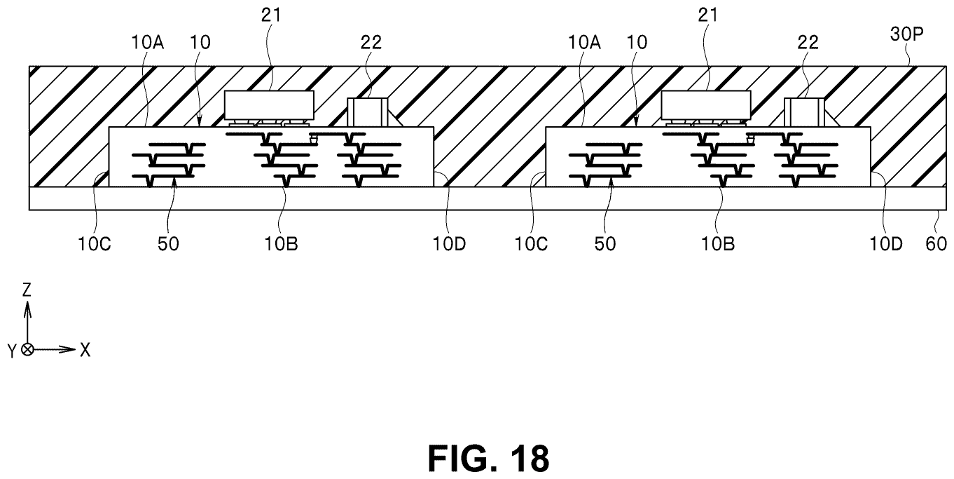

As shown in FIG. 18, in this step, the side surfaces 10C and 10D each of the plurality of main bodies 10 are still covered with the initial protective layer 30P.

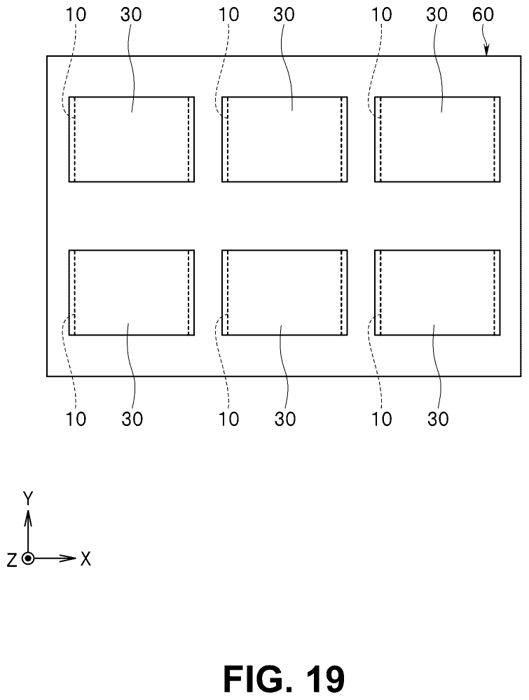

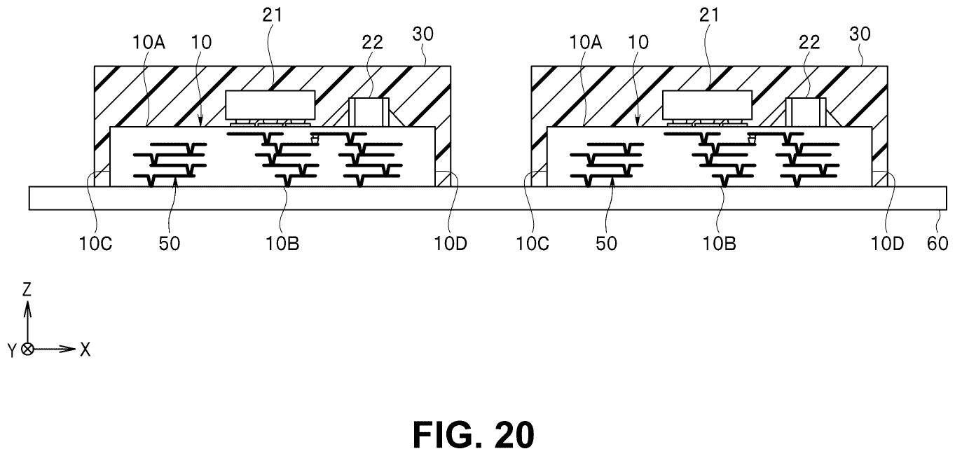

FIG. 19 and FIG. 20 show the subsequent step, in other words, the second cutting step S15. In this step, a part of the initial protective layer 30P is removed by cutting the initial protective layer 30P along each of the plurality of second dicing lines. In the second cutting step S15, the initial protective layer 30P is cut so as not to expose the side surfaces 10C and 10D of each of the plurality of main bodies 10. The initial protective layer 30P remaining after the second cutting step S15 serve as the plurality of protective layers 30.

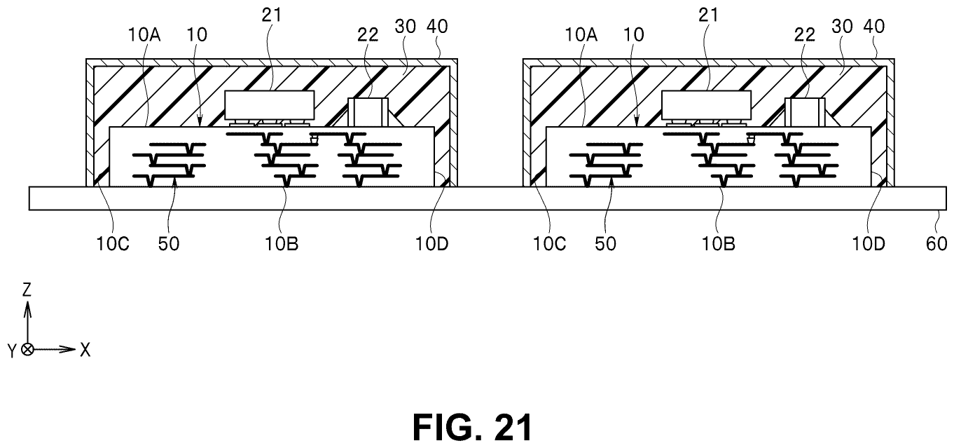

FIG. 21 shows the subsequent step, in other words, the shield layer formation step S16. In this step, the shield layer 40 is formed so as to cover each of the plurality of main bodies 10 and each of the plurality of protective layers 30.

In the method of manufacturing the module 1, after the step shown in FIG. 21, a step of separating the plurality of main bodies 10, each of which includes the protective layer 30 and the shield layer 40, from the substrate 60 is executed. With this, the plurality of modules 1 are completed.

Next, the operation and effects of the module 1 according to the example embodiment are described. In the example embodiment, the second covering parts 32 and 33 of the protective layer 30 cover the side surfaces 10C and 10D of the main body 10. With this, according to the example embodiment, reliability of the main body 10 and the module 1 can be improved while preventing damage to the main body 10. In particular, when the main body 10 is formed of a brittle material, damage to the main body 10 can be prevented more effectively due to the second covering parts 32 and 33.

In the example embodiment, the second covering parts 32 and 33 are covered with the second conductor parts 42 and 43 of the shield layer 40. According to the example embodiment, due to the second covering parts 32 and 33, the interval between the second conductor parts 42 and 43 and the plurality of conductor layers 50 provided inside the main body 10 can be increased. With this, according to the example embodiment, occurrence of stray capacitance between the second conductor parts 42 and 43 and the plurality of conductor layers 50 can be suppressed.

Herein, consideration is given to a case in which a coil configured by using the plurality of conductor layers 50 is provided inside the main body 10. When the coil is relatively far away from the side surface 10C or the side surface 10D, stray capacitance caused between the coil and the second conductor part 42 or the second conductor part 43 can be suppressed by up to approximately 4% due to the second covering parts 32 and 33. When the coil is relatively close to the side surface 10C or the side surface 10D, stray capacitance caused between the coil and the second conductor part 42 or the second conductor part 43 can be suppressed by up to approximately 23% due to the second covering parts 32 and 33.

In the example embodiment, the second covering parts 32 and 33 of the protective layer 30 do not cover the side surfaces 10E and 10F of the main body 10. The side surfaces 10E and 10F of the main body 10 are covered with the second conductor parts 44 and 45 of the shield layer 40. The connection electrodes 51 and 53 provided inside the main body 10 are connected to the second conductor part 44. The connection electrodes 52 and 54 provided inside the main body 10 are connected to the second conductor part 45. According to the example embodiment, the second conductor parts 44 and 45 can be connected to the ground via the connection electrodes 51 to 54. With this, according to the example embodiment, the function of the shield layer 40 can be exerted effectively.

In view of this, according to the example embodiment, the function of the shield layer 40 can be exerted effectively while improving reliability.

Incidentally, as a method of connecting the shield layer 40 to the ground, for example, a method of connecting the first conductor part 41 of the shield layer 40 and a ground terminal to each other via a first conductor embedded in the first covering part 31 of the protective layer 30 and a second conductor provided inside the main body 10 is conceived. However, in such a case, it is required to arrange the first conductor so as not to interfere with the electronic components 21 and 22 physically or characteristically, and it is also required to arrange the second conductor so as not to interfere with the electronic circuit inside the main body 10 physically or characteristically. With this, of the first surface 10A of the main body 10, an area of a region in which the electronic components 21 and 22 can be arranged can be reduced. At the same time, inside the main body 10, a volume of a region in which the electronic circuit can be arranged is reduced. As a result, there arises a problem that design of the main body 10 and the electronic components 21 and 22 is limited greatly. A step of forming the first conductor is required, which causes a problem in that the cost is increased.

In view of this, in the example embodiment, the first conductor is not required. In the example embodiment, as compared to the second conductor, the length of the conductor for connecting the second conductor parts 44 and 45 to the ground terminal can be reduced. In the example embodiment, by the series of steps S11 to S16 described above, the second conductor parts 44 and 45 can be connected to the connection electrodes 51 to 54. Based on those factors, according to the example embodiment, design limitations of the main body 10 and the electronic components 21 and 22 can be prevented, and the cost can be reduced.

In the example embodiment, the end portion of the second covering part 32 that is positioned at the end thereof in the −Z direction may not be covered with the second conductor part 42, and the end portion 33a of the second covering part 33 that is positioned at the end thereof in the −Z direction may not be covered with the second conductor part 43. In such a case, moisture or gas confined within the module 1 by the protective layer 30 can be released from those end portions. With this, corrosion of the main body 10 and the electronic components 21 and 22 can be suppressed.

In the example embodiment, the second conductor part 42 covers the side surface 10C of the main body 10 via the second covering part 32. With this, according to the example embodiment, the second conductor part 42 can be separated away from the terminals 111, 117, and 118 provided to the second surface 10B of the main body 10. With this, according to the example embodiment, a short circuit between the second conductor part 42 and the terminals 111, 117, and 118 can be prevented.

Similarly, the second conductor part 43 covers the side surface 10D of the main body 10 via the second covering part 33. With this, according to the example embodiment, the second conductor part 43 can be separated away from the terminals 113, 114, and 115 provided to the second surface 10B of the main body 10. With this, according to the example embodiment, a short circuit between the second conductor part 43 and the terminals 113, 114, and 115 can be prevented.

When the protective layer 30 is formed of a resin material, the shapes of the second conductor parts 42 and 43 can be flattened regardless of the shapes of the side surfaces 10C and 10D of the main body 10. For example, as shown in FIG. 9, even when the corner portion that is present at the position at which the second surface 10B and the side surface 10D of the main body 10 intersect with each other is rounded, the second covering part 33 can be flattened. With this, the second conductor part 43 can be flattened. The above-given description of the second covering part 33 and the second conductor part 43 is also applicable to the second covering part 32 and the second conductor part 42.

When the corner portion (31a) of the first covering part 31 of the protective layer 30 is rounded, the thickness of the first covering part 31 can be prevented from changing discontinuously between the part of the first conductor part 41 of the shield layer 40, which covers the top surface of the first covering part 31, and the part of the first conductor part 41 of the shield layer 40, which covers the first side surface to the fourth side surface of the first covering part 31.

When the corner portion that is present at the position at which the second surface 10B and the side surface 10F of the main body 10 intersect with each other is rounded, the second conductor part 45 can be prevented from changing discontinuously in the vicinity of the end portion 45a of the second conductor part 45. Similarly, when the corner portion that is present at the position at which the second surface 10B and the side surface 10E of the main body 10 intersect with each other is rounded, the second conductor part 44 can be prevented from changing discontinuously in the vicinity of the end portion of the second conductor part 44.

### Modification Examples

Next, a first modification example to a sixth modification example of the end portion of each of the second covering parts 32 and 33 of the protective layer 30 are described. Herein, the end portion 33a of the second covering part 33 is described as an example. The following description of the end portion 33a of the second covering part 33 is also applicable to the end portion of the second covering part 32.

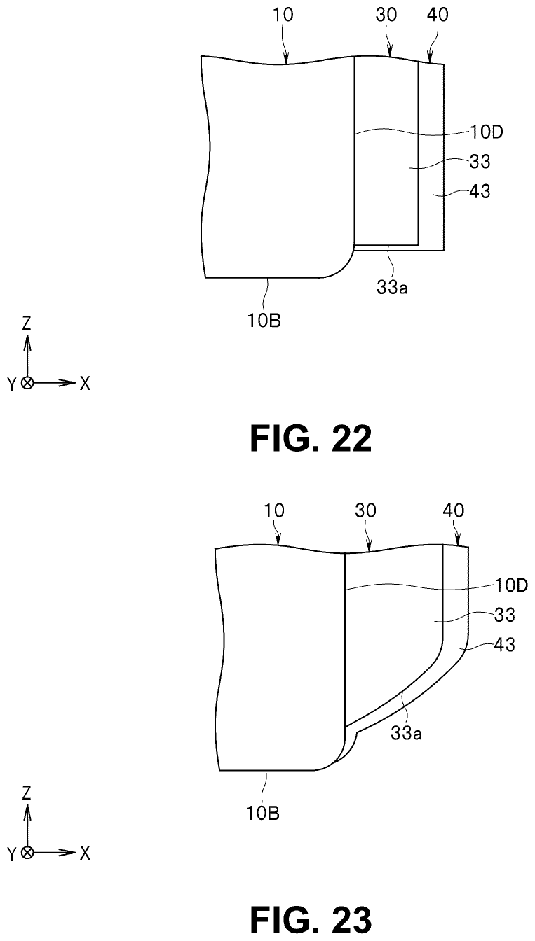

First, with reference to FIG. 22, the first modification example is described. FIG. 22 is a cross-sectional view showing the first modification example of the end portion 33a of the second covering part 33. In the first modification example, the end portion 33a of the second covering part 33 is positioned between the first surface 10A (see FIG. 1 and FIG. 2) and the second surface 10B of the main body 10 in a direction parallel to the Z direction.

According to the first modification example, the second conductor part 43 of the shield layer 40 covering the second covering part 33 (see FIG. 1, FIG. 6, and FIG. 7) can be separated further away from the terminals 113, 114, and 115 provided on the second surface 10B of the main body 10 (see FIG. 7). With this, according to the first modification example, a short circuit between the second conductor part 43 and the terminals 113, 114, and 115 can be prevented more effectively.

Note that the second conductor part 43 may or may not cover the end portion 33a of the second covering part 33.

Next, with reference to FIG. 23, the second modification example is described. FIG. 23 is a cross-sectional view showing the second modification example of the end portion 33a of the second covering part 33. In the second modification example, the shape of the end portion 33a of the second covering part 33 is different from that in the first modification example. As shown in FIG. 23, in the second modification example, at least a part of the end portion 33a of the second covering part 33 is inclined with respect to a direction perpendicular to the side surface 10D of the main body 10. Herein, a virtual plane that is parallel to an XY plane and includes the second surface 10B of the main body 10 is assumed. In the example shown in FIG. 23, in particular, a distance between a freely-selected position at the end portion 33a of the second covering part 33 and the virtual plane is increased as the freely-selected position is separated away from the side surface 10D of the main body 10.

The dimension of the second covering part 33 in the direction perpendicular to the side surface 10D of the main body 10 (a direction parallel to the X direction) is reduced as approaching the second surface 10B of the main body 10. The dimension of the second covering part 33 in the direction perpendicular to the second surface 10B of the main body 10 (a direction parallel to the Z direction) is reduced as being separated away from the side surface 10D of the main body 10.

In the second modification example, all of the end portion 33a of the second covering part 33 may be inclined with respect to the direction perpendicular to the side surface 10D of the main body 10. The end portion 33a of the second covering part 33 may have a shape protruding in a direction away from each of the first surface 10A and the side surface 10D of the main body 10 (see FIG. 1 and FIG. 2). The end portion 33a of the second covering part 33 may be rounded.

Note that the second conductor part 43 may or may not cover the end portion 33a of the second covering part 33. The second conductor part 43 may or may not cover the side surface 10D.

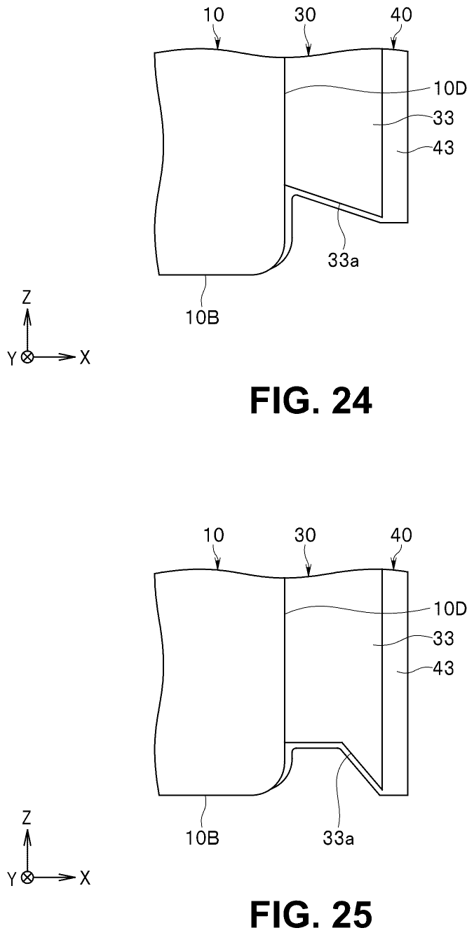

Next, with reference to FIG. 24, the third modification example is described. FIG. 24 is a cross-sectional view showing the third modification example of the end portion 33a of the second covering part 33. In the third modification example, the orientation of the inclination of the end portion 33a of the second covering part 33 is different from that in the second modification example. In the example shown in FIG. 24, a distance between a freely-selected position at the end portion 33a of the second covering part 33 and the virtual plane (the virtual plane including the second surface 10B of the main body 10) is reduced as the freely-selected position is separated away from the side surface 10D of the main body 10.

The dimension of the second covering part 33 in the direction perpendicular to the second surface 10B of the main body 10 (a direction parallel to the Z direction) is increased as being separated away from the side surface 10D of the main body 10.

Similarly to the second modification example, the second conductor part 43 may or may not cover the end portion 33a of the second covering part 33. The second conductor part 43 may or may not cover the side surface 10D.

Next, with reference to FIG. 25, the fourth modification example is described. FIG. 25 is a cross-sectional view showing the fourth modification example of the end portion 33a of the second covering part 33. In the fourth modification example, the shape of the end portion 33a of the second covering part 33 is different from that in the third modification example. As shown in FIG. 25, in the fourth modification example, the second covering part 33 includes the first part and the second part that is arranged such that the first part is sandwiched between the second part and the side surface 10D of the main body 10.

In the first part, a distance between a freely-selected position at the end portion 33a of the second covering part 33 and the virtual plane (the virtual plane including the second surface 10B of the main body 10) is constant or substantially constant regardless of the distance from the side surface 10D of the main body 10. In the second part, a distance between a freely-selected position at the end portion 33a of the second covering part 33 and the virtual plane is reduced as the freely-selected position is separated away from the side surface 10D of the main body 10.

The dimension of the first part of the second covering part 33 in the direction perpendicular to the second surface 10B of the main body 10 (a direction parallel to the Z direction) is constant or substantially constant regardless of the distance from the side surface 10D of the main body 10. The dimension of the second part of the second covering part 33 in the direction perpendicular to the second surface 10B of the main body 10 (a direction parallel to the Z direction) is increased as being separated away from the side surface 10D of the main body 10.

Similarly to the third modification example, the second conductor part 43 may or may not cover the end portion 33a of the second covering part 33. The second conductor part 43 may or may not cover the side surface 10D.

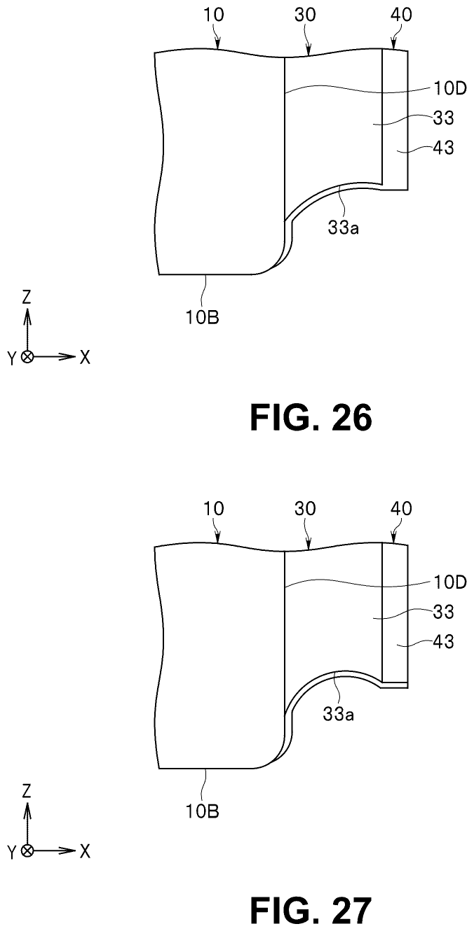

Next, with reference to FIG. 26, the fifth modification example is described. FIG. 26 is a cross-sectional view showing the fifth modification example of the end portion 33a of the second covering part 33. In the fifth modification example, the shape of the end portion 33a of the second covering part 33 is different from that in the second modification example. As shown in FIG. 26, in the fifth modification example, the end portion 33a of the second covering part 33 has a shape recessed in the Z direction. In the fifth modification example, the end portion 33a of the second covering part 33 may be rounded.

Similarly to the second modification example, the second conductor part 43 may or may not cover the end portion 33a of the second covering part 33. The second conductor part 43 may or may not cover the side surface 10D.

Next, with reference to FIG. 27, the sixth modification example is described. FIG. 27 is a cross-sectional view showing the sixth modification example of the end portion 33a of the second covering part 33. In the sixth modification example, the shape of the end portion 33a of the second covering part 33 is different from that in the fifth modification example. As shown in FIG. 27, in the sixth modification example, the second covering part 33 includes the first part where the dimension of the second covering part 33 in the direction perpendicular to the second surface 10B of the main body 10 (a direction parallel to the Z direction) is reduced as being separated away from the side surface 10D of the main body 10 and the second part where the dimension of the second covering part 33 in the direction perpendicular to the second surface 10B of the main body 10 (a direction parallel to the Z direction) is increased as being separated away from the side surface 10D of the main body 10. The first part is positioned between the side surface 10D of the main body 10 and the second part. In the sixth modification example, the end portion 33a of the second covering part 33 may be rounded.

Similarly to the fifth modification example, the second conductor part 43 may or may not cover the end portion 33a of the second covering part 33. The second conductor part 43 may or may not cover the side surface 10D.

### Second Example Embodiment

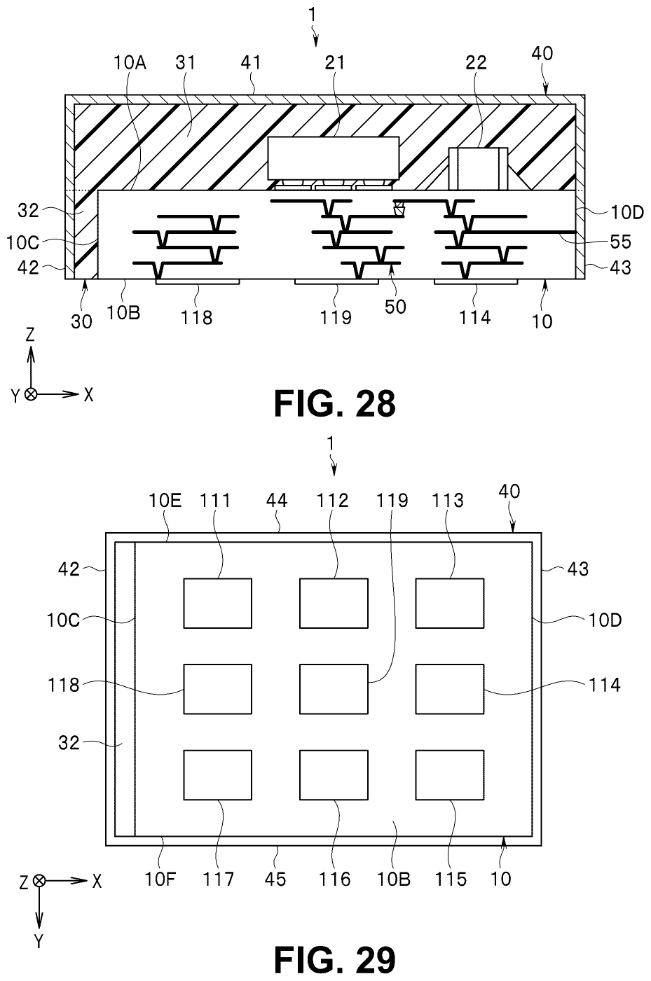

Next, with reference to FIG. 28 and FIG. 29, a second example embodiment of the present technique is described. FIG. 28 is a cross-sectional view showing the module according to the example embodiment. FIG. 29 is a plan view showing the module according to the example embodiment.

The configuration of the module 1 according to the example embodiment is different from that in the first example embodiment in the following respects. In the example embodiment, the second covering part of the protective layer 30 covers the side surface 10C without covering the side surfaces 10D, 10E, and 10F. In other words, in the example embodiment, the second covering part 33 is not provided. The second conductor part 43 of the shield layer 40 directly covers all or substantially all of the side surface 10D of the main body 10.

The plurality of conductor layers 50 may include at least one connection electrode connected to the second conductor part 43. FIG. 28 shows a connection electrode 55 connected to the second conductor part 43. The connection electrode 55 includes an end surface exposed at the side surface 10D. The second conductor part 43 is connected to the end surface of the connection electrode 55. An interval between the end surface of the connection electrode 55 and the second surface 10B in a direction parallel to the Z direction (hereinafter, referred to as a fifth interval) may be the same or substantially the same as an interval between the end surface of the connection electrode 55 and the first surface 10A in a direction parallel to the Z direction (hereinafter, referred to as a sixth interval), or may be different therefrom. In the latter case, the fifth interval may be smaller than the sixth interval.

The connection electrode 55 is an electrode connected to the ground. The connection electrode 55 is connected to at least one terminal of the terminals 111 to 119 via the plurality of conductor layers 50. At least one terminal to which the connection electrode 55 is connected is a ground terminal connected to the ground.

Note that the plurality of conductor layers 50 includes the connection electrode 55, at least one of the connection electrodes 51, 52, 53, and 54 (see FIG. 2, FIG. 4, and FIG. 5) may not be provided.

Next, the difference between the method of manufacturing the module 1 according to the example embodiment and that in the first example embodiment is described. In the example embodiment, the second cutting step S15 (see FIG. 11, FIG. 19, and FIG. 20) is different from that in the first example embodiment. In the second cutting step S15 in the example embodiment, the initial protective layer 30P is cut so as not to expose the side surface 10C of each of the plurality of main bodies 10. In the second cutting step S15 in the example embodiment, the initial protective layer 30P may further be cut so as to expose the side surface 10D of each of the plurality of main bodies 10. Alternatively, a part of each of the plurality of main bodies 10 may be cut together with the initial protective layer 30P. In such a case, one cross-section of the main body 10 serves as the side surface 10D.

The other configurations, operation, and effects of the example embodiment are similar to those of the first example embodiment.

### Third Example Embodiment

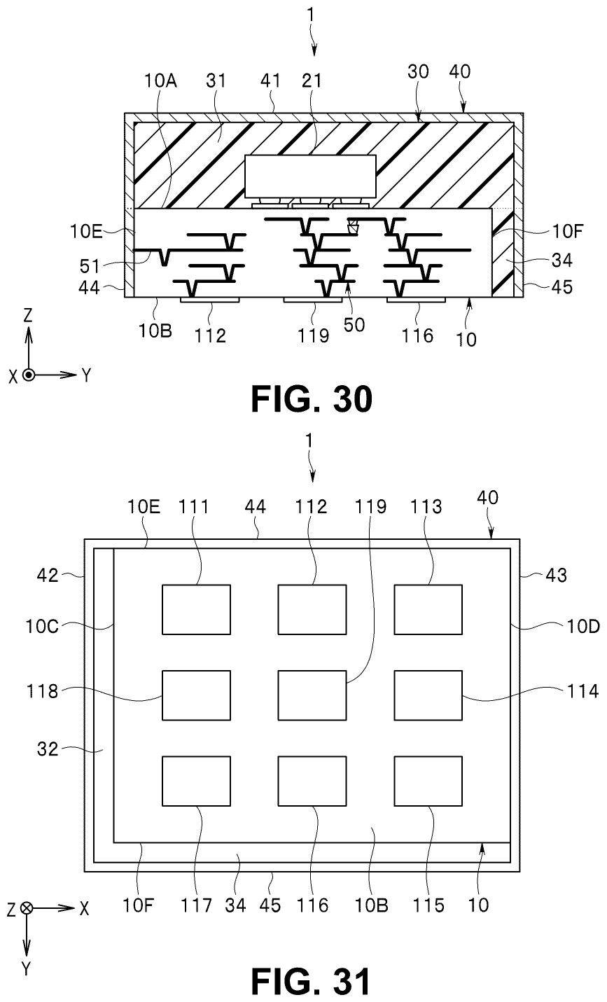

Next, with reference to FIG. 30 and FIG. 31, a third example embodiment of the present technique is described. FIG. 30 is a cross-sectional view showing the module according to the example embodiment. FIG. 31 is a plan view showing the module according to the example embodiment.

The configuration of the module 1 according to the example embodiment is different from that in the second example embodiment in the following respects. In the example embodiment, the second covering part of the protective layer 30 covers the side surfaces 10C and 10F without covering the side surfaces 10D and 10E. Hereinafter, a part of the second covering part that covers the side surface 10F is referred to as a second covering part 34. The second covering part 34 covers all or substantially all of the side surface 10F of the main body 10. The second covering part 34 is continuous with the first covering part 31 and the second covering part 32. In FIG. 30, the boundary between the first covering part 31 and the second covering part 34 is shown by the dotted line.

In the example embodiment, the second conductor part 45 of the shield layer 40 covers all or substantially all of the second covering part 34. The second conductor part 45 covers the side surface 10F of the main body 10 via the second covering part 34.

In the example embodiment, the connection electrodes 52 and 54 in the second example embodiment (the first example embodiment) are not provided.

The other configurations, operation, and effects of the example embodiment are similar to those of the second example embodiment.

### Fourth Example Embodiment

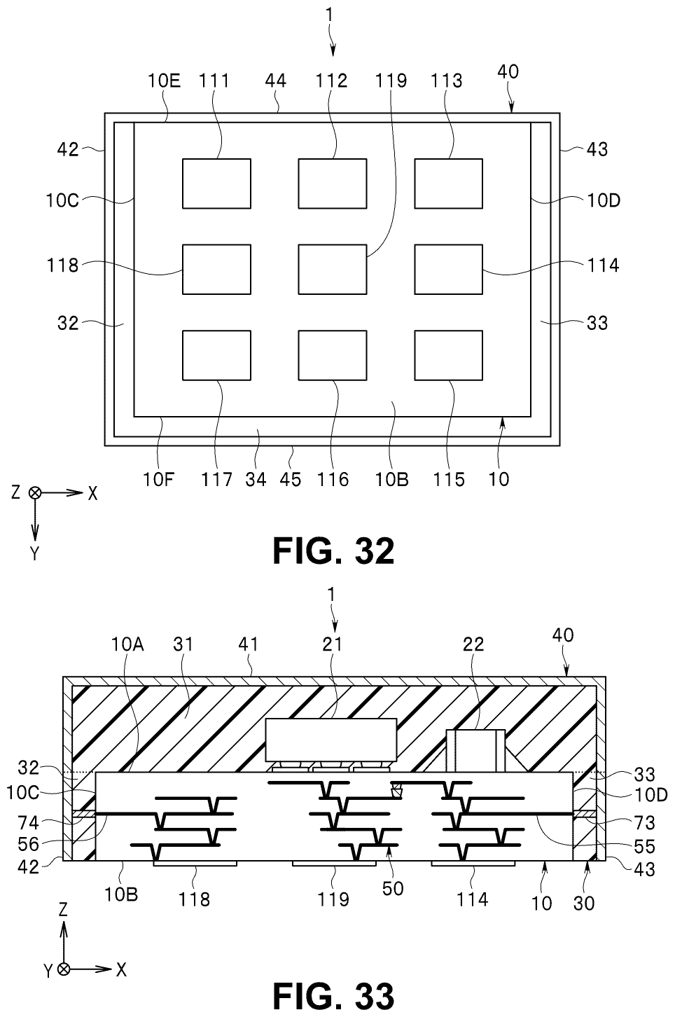

Next, with reference to FIG. 32, a fourth example embodiment of the present technique is described. FIG. 32 is a plan view showing the module according to the example embodiment.

The configuration of the module 1 according to the example embodiment is different from that in the third example embodiment in the following respects. In the example embodiment, the protective layer 30 covers the side surfaces 10C, 10D, and 10F without covering the side surface 10E. In the example embodiment, similarly to the third example embodiment, the connection electrodes 52 and 54 in the first example embodiment are not provided.

The other configurations, operation, and effects of the example embodiment are similar to those of the third example embodiment.

### Fifth Example Embodiment

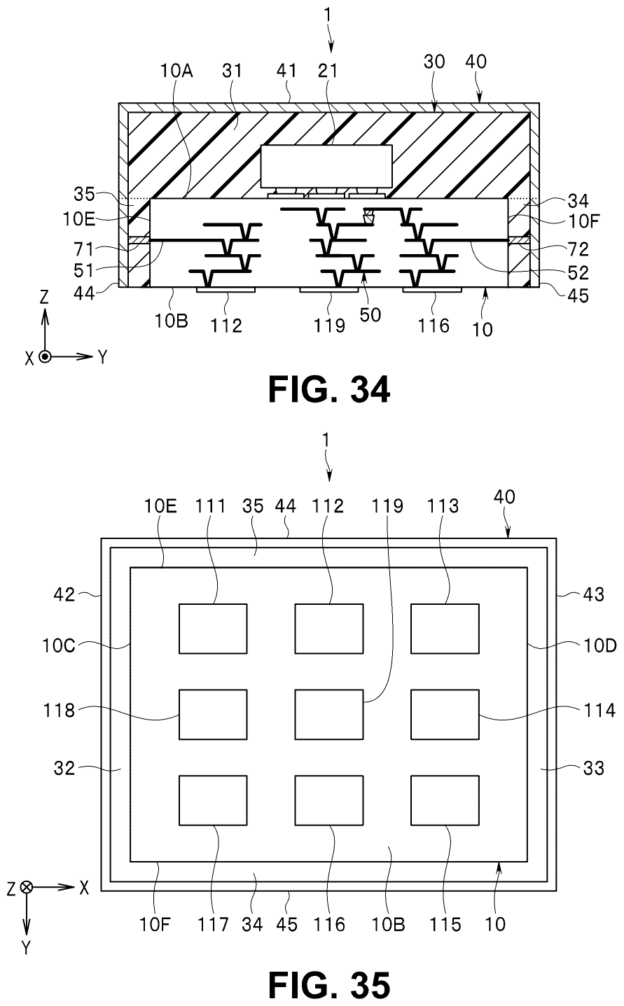

Next, with reference to FIG. 33 to FIG. 35, a fifth example embodiment of the present technique is described. FIG. 33 and FIG. 34 are cross-sectional views showing the module according to the example embodiment. FIG. 35 is a plan view showing the module according to the example embodiment.

The configuration of the module 1 according to the example embodiment is different from that in the fourth example embodiment in the following respects. In the example embodiment, the protective layer 30 covers the side surfaces 10C to 10F. Hereinafter, a part of the second covering part that covers the side surface 10E is referred to as a second covering part 35. The second covering part 35 covers all or substantially all of the side surface 10E of the main body 10. The second covering part 35 is continuous to the first covering part 31 and the second covering parts 32 and 33. In FIG. 34, the boundary between the first covering part 31 and the second covering parts 34 and 35 is shown by the dotted line.

In the example embodiment, the second conductor part 44 of the shield layer 40 covers all or substantially all of the second covering part 35. The second conductor part 44 covers the side surface 10E of the main body 10 via the second covering part 35.

The module 1 according to the example embodiment further includes a conductor layer 71 that connects the connection electrode 51 and the second conductor part 44 to each other and a conductor layer 72 that connects the connection electrode 52 and the second conductor part 45 to each other. The conductor layer 71 is embedded in the second covering part 35. The conductor layer 72 is embedded in the second covering part 34. Although omitted in illustration, the module 1 may further include a conductor layer that connects the connection electrode 53 (see FIG. 4) and the second conductor part 44 to each other and is embedded in the second covering part 35, and a conductor layer that connects the connection electrode 54 (see FIG. 5) and the second conductor part 45 to each other and is embedded in the second covering part 34.

The module 1 further includes a conductor layer 73 that connects the connection electrode 55 and the second conductor part 43 to each other. The conductor layer 73 is embedded in the second covering part 33.

The plurality of conductor layers 50 may further include at least one connection electrode connected to the second conductor part 42. FIG. 33 shows a connection electrode 56 connected to the second conductor part 42. The connection electrode 56 includes an end surface exposed at the side surface 10C. The module 1 further includes a conductor layer 74 that connects the connection electrode 56 and the second conductor part 42 to each other. The conductor layer 74 is embedded in the second covering part 32.

An interval between the end surface of the connection electrode 56 and the second surface 10B in a direction parallel to the Z direction (hereinafter, referred to as a seventh interval) may be the same or substantially the same as an interval between the end surface of the connection electrode 56 and the first surface 10A in a direction parallel to the Z direction (hereinafter, referred to as an eighth interval), or may be different therefrom. In the latter case, the seventh interval may be smaller than the eighth interval.

The connection electrode 56 is an electrode connected to the ground. The connection electrode 56 is connected to at least one terminal of the terminals 111 to 119 via the plurality of conductor layers 50. At least one terminal to which the connection electrode 56 is connected is a ground terminal that is connected to the ground.

The other configurations, operation, and effects of the example embodiment are similar to those of the fourth example embodiment.

Note that the present technique is not limited to each of the example embodiments described above, and various modifications may be made thereto. For example, in the method of manufacturing the module 1, the second cutting step S15 may be executed prior to the first cutting step S14.

The first covering part 31 of the protective layer 30 and the second covering part of the protective layer 30 may be formed of different materials. The first covering part 31 of the protective layer 30 and the second covering part of the protective layer 30 may be formed separately by using the same material or different materials.

As described above, an electronic circuit module according to an embodiment of the present technique includes a main body including a first surface and a second surface that face opposite to each other, and four side surfaces that connect the first surface and the second surface to each other, a plurality of conductor layers provided inside the main body, an electronic component mounted on the first surface of the main body, a protective layer formed of an insulating material, and a shield layer formed of a conductive material. The protective layer includes a first covering part that covers the electronic component and the first surface and a second covering part that covers at least one side surface of the four side surfaces. The shield layer includes a first conductor part that covers the electronic component and the first covering part and a second conductor part that covers the main body and the second covering part. The plurality of conductor layers include at least one connection electrode connected to the second conductor part.

In the electronic circuit module according to the embodiment of the present technique, the four side surfaces may include a first side surface and a second side surface. The second covering part may cover the first side surface without covering the second side surface. The second conductor part may cover the first side surface via the second covering part, and may directly cover the second side surface. The at least one connection electrode may include an end surface exposed at the second side surface. The second conductor part may be connected to the end surface. The four side surfaces may further include a third side surface and a fourth side surface. The second covering part may cover the first side surface and the third side surface without covering the second side surface and the fourth side surface. The second conductor part may cover the first side surface and the third side surface via the second covering part, and may directly cover the second side surface and the fourth side surface. The first side surface and the third side surface may face opposite to each other. The second side surface and the fourth side surface may face opposite to each other. The at least one connection electrode may be a first connection electrode and a second connection electrode. The first connection electrode may include a first end surface exposed at the second side surface. The second connection electrode may include a second end surface exposed at the fourth side surface. The second conductor part may be connected to the first end surface and the second end surface.

In the electronic circuit module according to the embodiment of the present technique, the main body may include a plurality of insulating layers being stacked. The first surface and the second surface may be positioned at both ends of the main body in a stacking direction of the plurality of insulating layers.

In the electronic circuit module according to the embodiment of the present technique, the main body may be formed of a brittle material.

In the electronic circuit module according to the embodiment of the present technique, the protective layer may contain a resin material.

In the electronic circuit module according to the embodiment of the present technique, the shield layer may include a plurality of metal layers being stacked.

The electronic circuit module according to the embodiment of the present technique further may include a terminal arranged on the second surface. The at least one connection electrode may be electrically connected to the terminal. The terminal may be a ground terminal that is connected to the ground.

In the electronic circuit module according to the embodiment of the present technique, the first covering part may include a rounded corner portion.

In the electronic circuit module according to the embodiment of the present technique, the second covering part may include an end portion that is farthest from the first covering part and is rounded.

In the electronic circuit module according to the embodiment of the present technique, the second covering part may include an end portion that is farthest from the first covering part. The end portion may be positioned between the first surface and the second surface in a direction perpendicular to the first surface.

A method of manufacturing an electronic circuit module according to an embodiment of the present technique includes forming the main body and the plurality of conductor layers, mounting the electronic component on the main body, forming an initial protective layer so as to cover the main body and the electronic component, removing a part of the initial protective layer and forming the protective layer so as to form the first covering part and the second covering part, and forming the shield layer.

In the electronic circuit module and the method of manufacturing the same of the present technique, the second covering part covers at least one side surface of the four side surfaces, and the second conductor part covers the main body and the second covering part. The plurality of conductor layers include at least one connection electrode connected to the second conductor part. With this, the present technique can exert an effect that an electronic circuit module capable of effectively exerting a function of a shield layer can be achieved while improving reliability.

Obviously, many modifications and variations of the present disclosure are possible in the light of the description given above. Thus, within the scope of the appended claims and equivalents thereof, the present disclosure may also be practiced in embodiments other than the example embodiments described above.

1. An electronic circuit module comprising:

[symbol]

2. The electronic circuit module according to claim 1, wherein

[symbol]

3. The electronic circuit module according to claim 2, wherein

[symbol]

4. The electronic circuit module according to claim 2, wherein surface,

[symbol]

5. The electronic circuit module according to claim 4, wherein

[symbol]

6. The electronic circuit module according to claim 4, wherein

[symbol]

7. The electronic circuit module according to claim 1, wherein

[symbol]

8. The electronic circuit module according to claim 1, wherein

[symbol]

9. The electronic circuit module according to claim 1, wherein

[symbol]

10. The electronic circuit module according to claim 1, wherein

[symbol]

11. The electronic circuit module according to claim 1, further comprising:

[symbol]

12. The electronic circuit module according to claim 11, wherein

[symbol]

13. The electronic circuit module according to claim 1, wherein

[symbol]

14. The electronic circuit module according to claim 1, wherein

[symbol]

15. The electronic circuit module according to claim 1, wherein

[symbol]

16. A method of manufacturing the electronic circuit module according to claim 1, the method comprising:
forming the main body and the plurality of conductor layers;
mounting the electronic component on the main body;
forming an initial protective layer so as to cover the main body and the electronic component;
removing a part of the initial protective layer and forming the protective layer so as to form the first covering part and the second covering part; and
forming the shield layer.
